(19) United States
(12) Patent Application Publication
(10) Pub. No.: US 2013/0082013 A1
(43) Pub. Date: Apr. 4, 2013

(54) FIXING DEVICE FOR DATA STORAGE DEVICE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/406,539

(22) Filed: Feb. 28, 2012

(30) Foreign Application Priority Data
Sep. 29, 2011 (CN) 201110297506.X

(51) Int. Cl. H05K 7/18

(52) U.S. Cl. 211/26

(57) ABSTRACT

A fixing device for fixing a data storage device includes a rack, an engaging member, and a resilient member. The rack includes a bottom plate, a first plate and a second plate protruding from the bottom plate. The resilient member is fixed to the bottom plate is permanently deformed by, and bears against, the data storage device when in place. Two pins protrude from an inner surface of the first plate to detachably engage in a first sidewall of the data storage device. A stopping tab extends from the engaging member to detachably block a top of the data storage device.

### BACKGROUND

1. Technical Field

The present disclosure relates to means of affixation for data storage devices.

2. Description of Related Art

An electronic device, such as a computer, may be equipped with data storage devices, such as an optical disk drive. Mounting the optical disk drive to the electronic device with screws is inefficient and requires the use of a tool, such as a screwdriver, which is inconvenient.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fixing device, together with an optical disk drive (ODD).

FIG. 2 is an assembled, isometric view of the fixing device and the ODD of FIG. 1.

FIG. 3 is similar to FIG. 2, but showing the fixing device in another state.

FIG. 4 is an inverted, enlarged view of the ODD of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

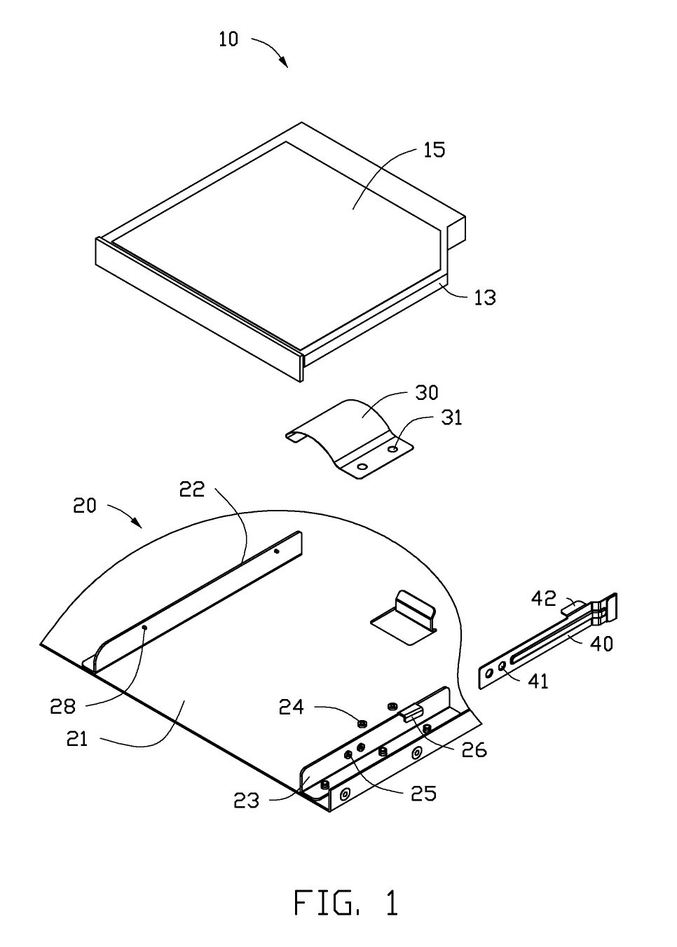

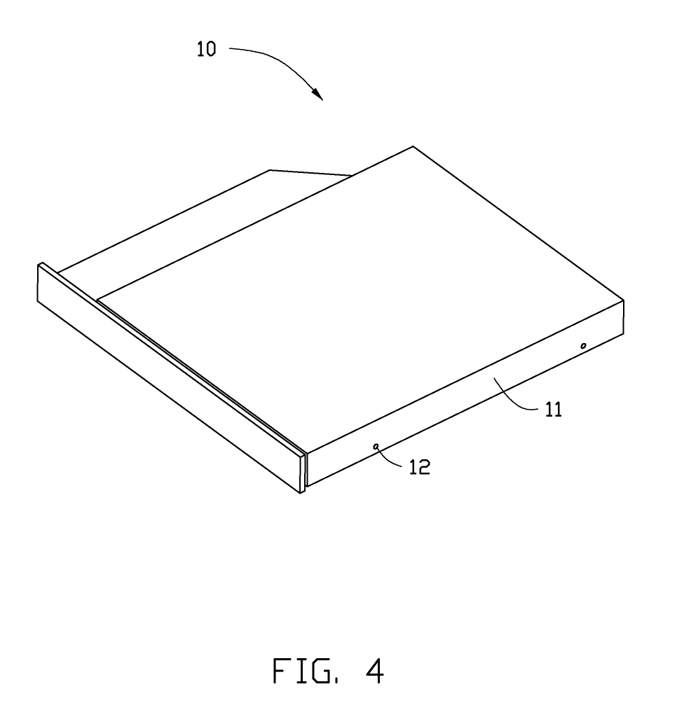

Referring to FIGS. 1 and 4, an exemplary embodiment of a fixing device for fixing a data storage device, such as an optical disk drive (ODD) 10, includes a rack 20, a resilient member 30, and an engaging member 40. In the embodiment, the resilient member 30 is a sheet of resilient metal (resilient metal sheet 30).

The ODD 10 includes a first sidewall 11, a second sidewall 13 opposite to the first sidewall 11, and a top wall 15 connected between top sides of the first and second sidewalls 11 and 13. Two holes 12 are defined in the first sidewall 11.

The rack 20 includes a bottom plate 21, a first plate 22 perpendicularly extending up from the bottom plate 21, and a second plate 23 perpendicularly extending up from the bottom plate 21. The second plate 23 is parallel to the first plate 22. Two spaced protrusions 24 protrude from the bottom plate 21, adjacent to the inner side surface of the second plate 23. Two spaced pins 28 perpendicularly extend from the inner side surface of the first plate 22. Two spaced protrusions 25 protrude from the outer side surface of the second plate 23, adjacent to a first end of the second plate 23. An L-shaped limitation portion 26 extends from the top of the second plate 23, adjacent to a second end of the second plate 23. The limitation portion 26 perpendicularly extends out from the second plate 23, and then extends down.

The resilient member 30 is arced up to resemble a shallow arch. Two spaced holes 31 are defined in a first end of the resilient member 30.

The engaging member 40 is substantially bar-shaped. Two spaced holes 41 are defined in a first end of the engaging member 40. A stopping tab 42 perpendicularly extends from the top of the engaging member 40, adjacent to a second end of the engaging member 40.

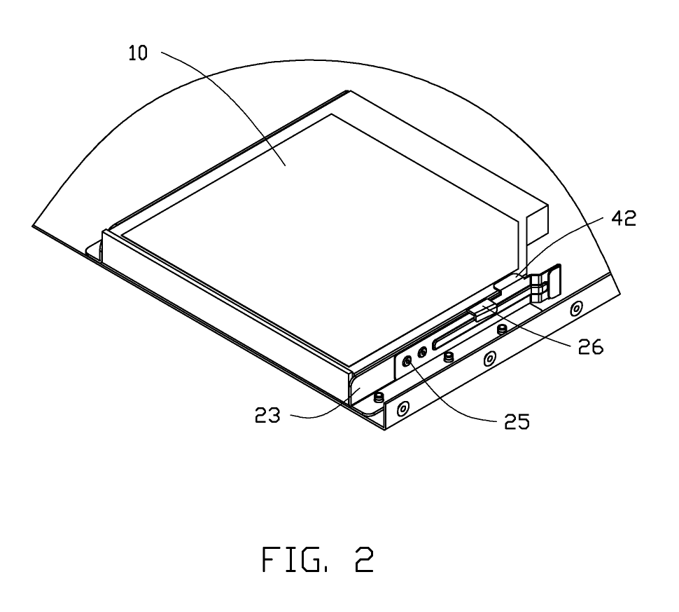

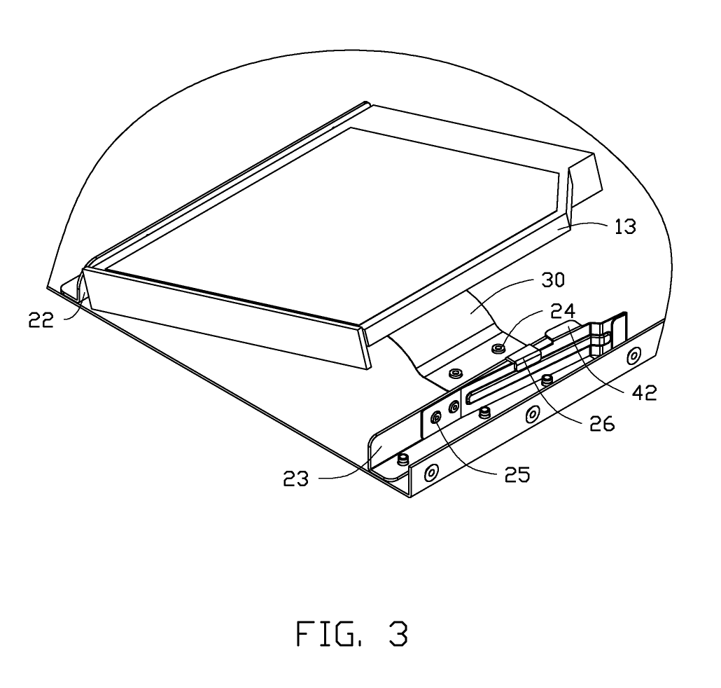

Referring to FIGS. 2 and 3, in assembly, the protrusions 24 are extended through the holes 31, and the resilient member 30 is riveted to the protrusions 24. The first end of the engaging member 40 is extended through a space between the second plate 23 and the limitation portion 26. The protrusions 25 are aligned with and extended through the holes 41, and then the engaging member 40 is riveted to the protrusions 25. The engaging member 40 abuts the outer side surface of the second plate 23. The stopping tab 42 is above the second plate 23. The limitation portion 26 is provided to keep the engaging member 40 captive within a small predetermined angular range with respect to the second plate 23, so as not to deprive the engaging member 40 of resilience when pulled out.

To fix the ODD 10 in place, the second end of the engaging member 40 is pulled away from the second plate 23 until limited by the stopping tab 42. The pins 28 engage in the holes 12. The ODD 10 is manipulated down to allow the second sidewall 13 to abut the inner side surface of the second plate 23. The first sidewall 11 abuts the inner side surface of the first plate 22. The ODD 10 abuts against the topmost middle part of the resilient member 30, to deform it down toward the bottom plate 21. The engaging member 40 is loosened, to allow the second end of the engaging member 40 to abut the second plate 23. The top wall 15 is blocked by the stopping tab 42.

To detach the ODD 10, the second end of the engaging member 40 is pulled away from the second plate 23 until limited by the stopping tab 42. The resilient member 30 self-restores to push up the ODD 10. The ODD 10 is lifted up, to allow the pins 28 to disengage from the holes 12. Thereby, the ODD 10 is disassembled from the rack 20.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fixing device for fixing a data storage device, comprising:
a rack comprising a bottom plate, a first plate perpendicularly extending up from the bottom plate to abut a first sidewall of the data storage device, and a second plate perpendicularly extending up from the bottom plate and parallel to the first plate to abut a second sidewall of the data storage device opposite to the first sidewall, two pins protruding from an inner surface of the first plate toward the second plate to detachably engage in the first sidewall of the data storage device;
a resilient member fixed to the bottom plate to be resiliently sandwiched between the bottom plate and the data storage device; and
an engaging member comprising a first end fixed to an outer surface of the second plate, and a second end operable to be deformed away from the second plate, a stopping tab extending towards the first plate from a top of the second end of the engaging member, to detachably block a top of the data storage device.

2. The fixing device of claim 1, wherein an L-shaped limitation portion extends outward from the top of the second plate, to limit the deformation of the engaging member.

3. The fixing device of claim 1, wherein the resilient member is a sheet of resilient metal, the resilient member is arced up to form a shallow arch, an end of the resilient member is fixed to the bottom plate.
